(19) United States
(12) Patent Application Publication
(10) Pub. No.: US 2008/0057603 A1
(43) Pub. Date: Mar. 6, 2008

(54) Light Emitting Diode and Method of Making the Same

(76) Inventors: Pai-Hsiang Wang, Chung Li City (TW); Chih-Sung Chang, Hsinchu (TW); Tzer-Perng Chen, Hsinchu (TW)

Correspondence Address: GLENN PATENT GROUP, 3475 EDISON WAY, SUITE L, MENLO PARK, CA, 94025, US

(21) Appl. No.: 11/936,613

(22) Filed: Nov. 7, 2007

Related U.S. Application Data
(62) Division of application No. 10/866,472, filed on Jun. 10, 2004.

(51) Int. Cl. H01L 33/00

(52) U.S. Cl. 438/27; 257/E33.056

(57) ABSTRACT

A light emitting diode (LED) and a method of making the same are disclosed. The present invention is featured in that the LED comprises a transparent heat-conductive glue, a reflective layer, and a carrier, etc, wherein the transparent heat-conductive glue is used to adhere the epitaxial structure and the carrier of the LED; the reflective layer can make the light emitted by the epitaxial structure to be reflected more efficiently; and the carrier is used to enhance the heat-dissipation effect of the LED. Moreover, the transparent heat-conductive glue and the reflective layer can be replaced with one single adhesive reflective layer having functions of adhesion and reflection simultaneously.

### CROSS-REFERENCE TO RELATED APPLICATIONS

This application is a divisional application of U.S. Ser. No. 10/866,472 filed Jun. 10, 2004.

### TECHNICAL FIELD

The present invention relates to a light emitting diode (LED) and a method of making the same, and more particularly, to a LED having a carrier that can enhance heat-dissipation effect and a method of making the LED.

### BACKGROUND

In recent years, a great deal of attention has been directed to the light-emitting device utilizing gallium nitride-based semiconductors such as GaN, AlGaN, InGaN, and AlInGaN, etc. Usually, most of the light-emitting devices of the aforementioned type are grown on an electrically insulating substrate such as sapphire, GaN, AlN, etc., that are different from other light-emitting devices utilizing conductive substrates. Since the sapphire substrate is an insulator, the electrodes cannot be directly formed on the substrate, and has to directly contact the P-type semiconductor layer and the N-type semiconductor layer individually so as to complete the manufacturing of the light-emitting device formed on the sapphire substrate.

Please refer to FIG. 1 showing the cross section of the conventional nitride LED. A LED 80 shown in FIG. 1 can be formed via the following steps. Firstly, a nucleation layer 20 is formed on a substrate 10, wherein the material of the substrate 10 is such as sapphire, GaN, AlN, etc. Then, a semiconductor layer 30 of a first polarity, a multi quantum well structure 40, and a semiconductor layer 50 of a second polarity are sequentially epitaxially grown on the nucleation layer 20. Afterwards, the aforementioned epitaxial layers are etched, thereby exposing a portion of the semiconductor layer 30 of the first polarity. Then, an electrode 60 of the first polarity and an electrode 70 of the second polarity are deposited respectively on the exposed portion of the semiconductor layer 30 of the first polarity and the semiconductor layer 50 of the second polarity via thermal evaporation, e-beam evaporation, or sputtering, etc.

The aforementioned substrate 10 can be made of material such as sapphire, GaN, AlN, etc. The thermal conductivity of sapphire is about 35˜40 W/(m.K), that will cause poor conducting effect to the heat generated by the LED 80 when it emits light, make the heat resistance of one single chip too large, and therefore cause poor light emitting efficiency to high current application.

Please refer to FIG. 2 showing packaging of the conventional nitride LED. As shown in FIG. 2, a welding wire 62 and a welding wire 72 are connected to the electrode 60 of the first polarity and the electrode 70 of the second polarity of the LED 80 respectively, thereby making the LED 80 to be electrically connected to an external power or other elements. When the LED chip is packaged and fixed, the wood glue 94 pervious to light is always used to adhere the LED 80 onto a metal cup 90 and the metal cup 90 is connected to a base 92 since the substrate 10 made of material such as sapphire etc. is pervious to light, thereby enabling the light below to be reflected by the metal cup 90 and thus enhancing light emitting effect. However, the thermal conductivity of the general wood glue 94 is still not good. Moreover, when the wood glue 94 is replaced by silver paste, it is possible for silver paste or solder to absorb light; therefore the usage of the LED 80 is limited.

Furthermore, the hardness of the sapphire material is very large, therefore the related process such as cutting cannot be performed easily. Besides, since sapphire is an insulator, therefore it is necessary to dispose the electrodes on the same side of the LED, causing that the design of LED faces the problem that the light emitting area is occupied; at the same time, the aforementioned issue is not convenient for subsequent test and packaging.

One of the conventional solutions to the aforementioned AlInGaN LED is flip chip; however, the processes of such as reflective layer and flip chip, etc. in this method have certain difficulties.

Consequently, since the LEDs in the future will be developed toward application market needing higher brightness, therefore the operating current and power of a single LED will be in the range of several times to several hundred times as much as the present ones. At the same time, that how to apply and solve the light generated by LED and the heat produced subsequently effectively will be a very important and measurable problem.

### SUMMARY

Consequently, an objective of the present invention is to provide a LED and a method of making the same, wherein the thickness of the substrate is shortened and even eliminated completely, thereby reducing the heat resistance of LED remarkably.

Another objective of the present invention is to provide a LED and a method of making the same, wherein the carrier under the epitaxial structure can take out the heat generated by the epitaxial structure, thereby reducing the heat resistance of LED remarkably.

Still another objective of the present invention is to provide a LED and a method of making the same, wherein the reflective layer above the carrier can reflect the light emitted by the epitaxial structure.

Further another objective of the present invention is to provide a LED and a method of making the same, wherein two electrodes of LED can be disposed on the upper surface of the epitaxial structure and the lower surface of the carrier respectively while the carrier is a conductor, thereby reducing the light-blocking area of the electrode.

According to the aforementioned objectives of the present invention, the present invention provides a LED, comprising: a carrier used to transfer heat generated by the LED, wherein a reflective layer is located on the carrier; and an epitaxial structure disposed on the carrier by a transparent heat-conductive glue, wherein the epitaxial structure comprises a plurality of III-V compound semiconductor epitaxial layers, wherein light is generated when a current enters the LED.

According to the aforementioned objectives of the present invention, the present invention provides another LED, comprising: a carrier used to transfer heat generated by the LED; an adhesive reflective layer located on the carrier; and an epitaxial structure disposed on the adhesive reflective layer, wherein the epitaxial structure comprises a plurality of III-V compound semiconductor epitaxial layers, wherein light is generated when a current enters the LED.

According to the aforementioned objectives of the present invention, the present invention provides a method of making a LED, comprising: providing a carrier used to transfer heat generated by the LED; providing an epitaxial structure comprising a plurality of III-V compound semiconductor epitaxial layers, wherein light is generated when a current enters the LED; and using an adhesive reflective layer to adhere the carrier and the epitaxial structure. Moreover, the adhesive reflective layer further comprises a reflective layer and a transparent heat-conductive glue, wherein the reflective layer is located on the carrier; and the transparent heat-conductive glue is used to adhere the carrier and the epitaxial structure.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a diagram showing the cross section of the conventional nitride LED;

FIG. 2 is a diagram showing packaging of the conventional nitride LED;

FIG. 3A is a diagram showing the cross section of the LED according to an embodiment of the present invention;

FIG. 3B is a diagram showing the cross section of the LED according to another embodiment of the present invention;

FIG. 4 is a diagram showing the cross section of the LED according to another embodiment of the present invention;

FIG. 5 is a diagram showing the cross section of the LED according to still another embodiment of the present invention; and

FIG. 6 is a diagram showing the cross section of the LED according to even another embodiment of the present invention.

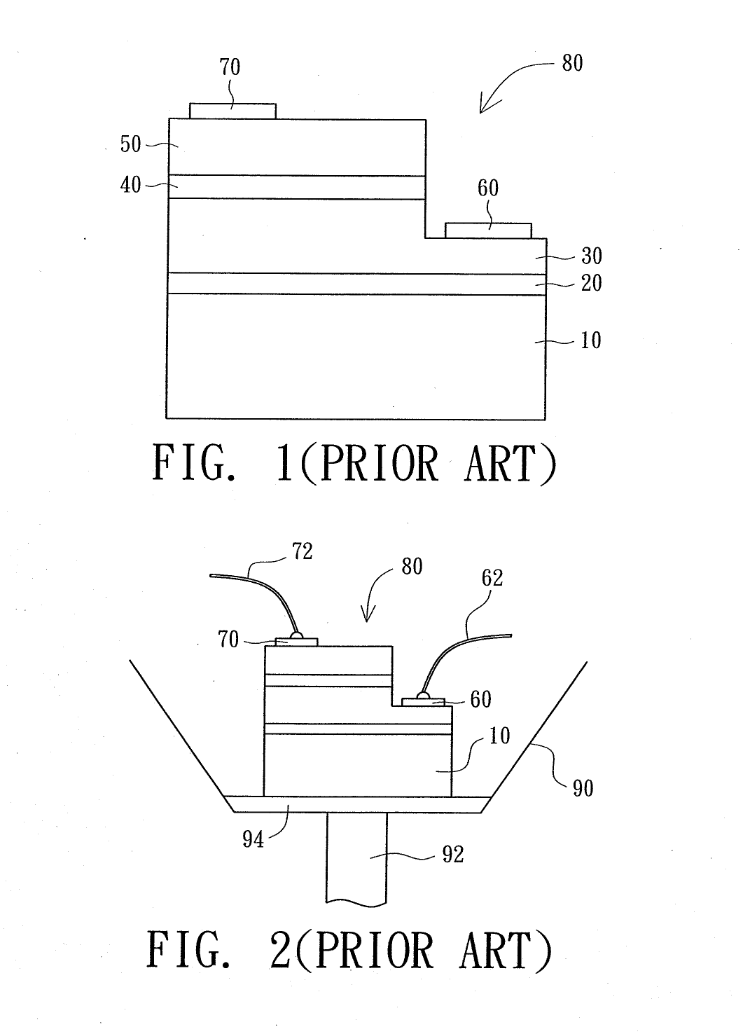

### DETAILED DESCRIPTION OF THE PREFERRED EMBODIMENTS

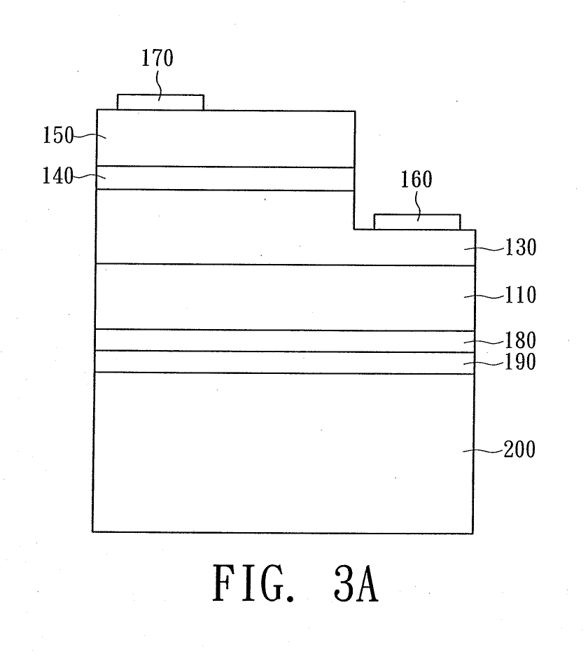

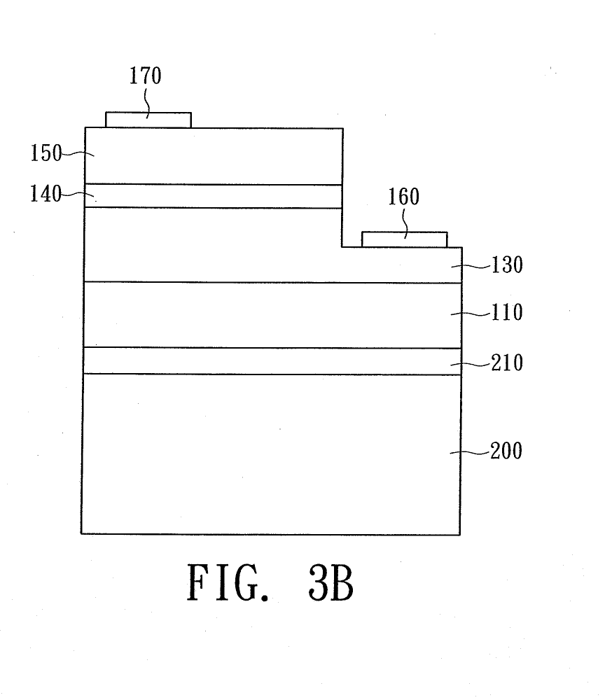

The present invention relates to a LED having a carrier that can enhance heat-dissipation effect and a method of making the LED, wherein the LED comprises a plurality of semiconductor epitaxial layers made of III-V compounds such as AlInGaN, etc. Please refer to FIG. 3A showing the cross section of the LED according to an embodiment of the present invention. The LED as shown in FIG. 3A can be formed via the following process. Firstly, a substrate 110 is provided, wherein the substrate 110 can be made of material such as sapphire, GaN, or AlN, etc. Then, a semiconductor layer 130 of a first polarity, a multi quantum well structure 140, and a semiconductor layer 150 of a second polarity are sequentially epitaxially grown on the nucleation layer 20. Afterwards, the aforementioned epitaxial structure is etched, thereby exposing a portion of the semiconductor layer 130 of the first polarity. Then, an electrode 160 of the first polarity and an electrode 170 of the second polarity are deposited respectively on the exposed portion of the semiconductor layer 130 of the first polarity and the semiconductor layer 150 of the second polarity via thermal evaporation, e-beam evaporation, or sputtering, etc. It is worth describing that both the first polarity and the second polarity mentioned in the present invention are mutually opposite polarities. For example, the second polarity is N type while the first polarity is P type; the second polarity is P type while the first polarity is N type.

Afterwards, the substrate 110 can be polished or etched so as to shorten the thickness of the substrate 110 to about 10 μm-50 μm or even thinner. Then, a carrier 200 is provided, wherein the carrier 200 can be mainly made of metal material having high thermal conductivity, such as copper, silver, aluminum, or gold, etc. (including the compound), or other non-metal material such as silicon, GaN, AlN, diamond, or SiC, etc. (including the compound). Moreover, a reflective layer 190 is formed on the carrier 200, wherein the reflective layer 190 is made of material having high reflectivity, such as silver, gold, or aluminum, etc., thereby making the light emitted by the above epitaxial structure to be reflected more efficiently by the reflective layer 190. Afterwards, a heat-conductive glue 180 can be used to adhere the aforementioned epitaxial structure and the substrate 110 onto the carrier 200 having the reflective layer 190, wherein the heat-conductive glue 180 can be made of material such as silicon glue or epoxy, etc.

With the use of the aforementioned structure and process of LED of the present invention, heat resistance can be reduced remarkably since the thickness of the substrate 110 is shortened. Moreover, the carrier 200 that is adhered under the substrate 110 and that is able to transfer heat well can enable heat to be dissipated out more rapidly, thereby reducing rapidly the heat produced in the multi quantum well structure 140. Furthermore, in addition to wood glue, solder such as silver paste, indium, or tin, etc. can be used to perform adherence in subsequently packaging and fixing of chip under the carrier 200, thereby enabling this kind of LED to be used in wider range more extensively.

Please refer to FIG. 3B showing the cross section of the LED according to another embodiment of the present invention. The difference between FIG. 3B and FIG. 3A is that the transparent heat-conductive glue 180 and the reflective layer 190 shown in FIG. 3A can be replaced with one single adhesive reflective layer 210 having functions of adhesion and reflection simultaneously as shown in FIG. 3B, thereby being used in larger range, wherein the adhesive reflective layer 210 can be made of material such as metal.

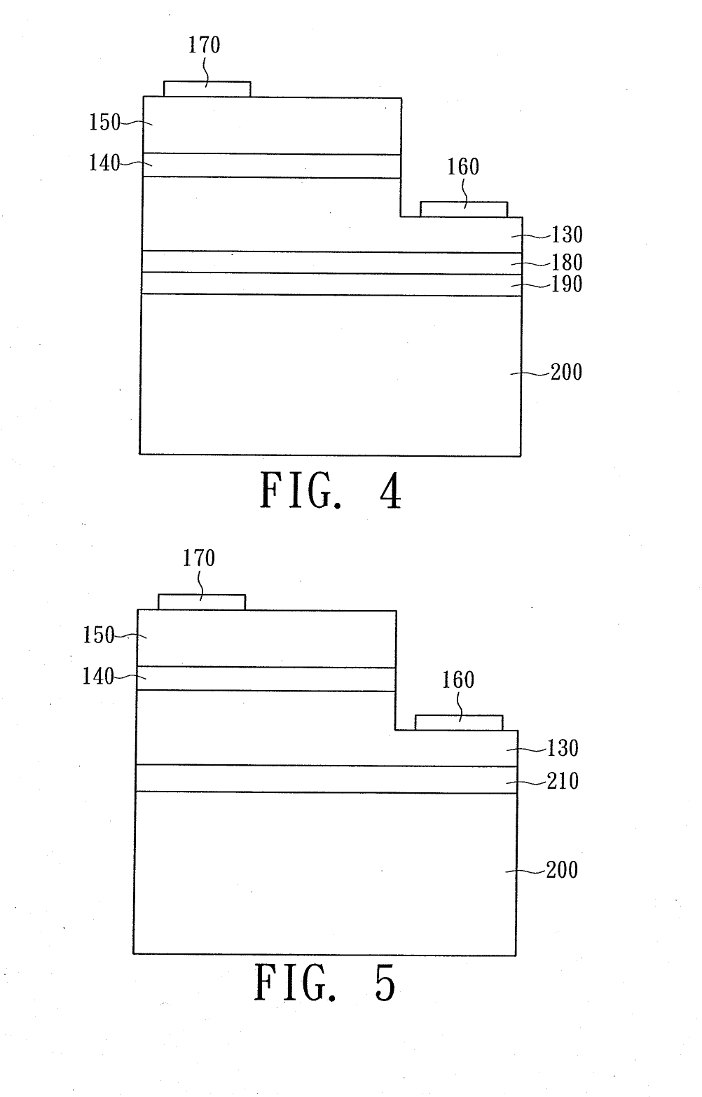

Please refer to FIG. 4 showing the cross section of the LED according to another embodiment of the present invention. The difference between FIG. 4 and FIG. 3A is that in FIG. 4, there is no substrate 110 as shown in FIG. 3A since the substrate has been eliminated completely via polishing, etching, or removing in the present embodiment. Consequently, the heat resistance of LED in the present invention can be reduced further; and thus the light emitting efficiency can be heightened.

Please refer to FIG. 5 showing the cross section of the LED according to still another embodiment of the present invention. The difference between FIG. 5 and FIG. 4 is that the transparent heat-conductive glue 180 and the reflective layer 190 shown in FIG. 4 can be replaced with one single adhesive reflective layer 210 having functions of adhesion and reflection simultaneously as shown in FIG. 5, thereby being used in larger range, wherein the adhesive reflective layer 210 can be made of material such as metal.

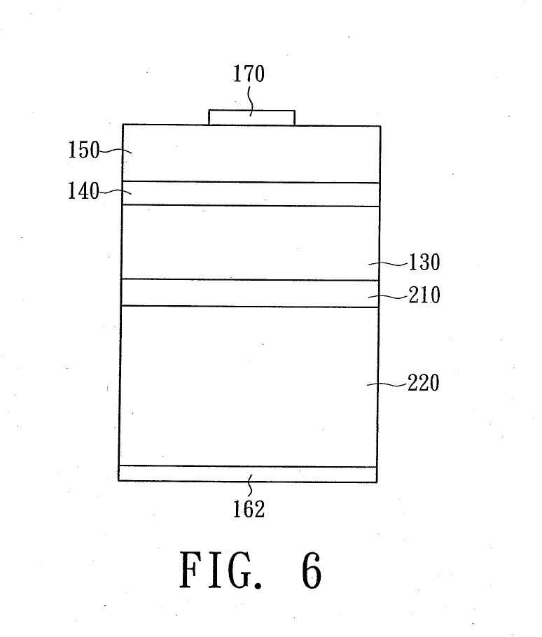

In the aforementioned embodiments as shown in FIG. 3A to FIG. 5, the carrier 200 can be a conductor having high thermal conductivity or an insulator having high thermal conductivity. If the carrier 200 is a conductor having high thermal conductivity, the present invention can be changed further like the even another embodiment as shown in FIG. 6. In FIG. 6, the carrier 220 is a conductor; and therefore the two electrodes of LED can be disposed on the upper surface of the epitaxial structure and the lower surface of the carrier 220 respectively. That is, the electrode 162 of the first polarity of LED is located on the lower surface of the carrier 220; and the electrode 170 of the second polarity is located on the upper surface of the epitaxial structure, thereby reducing the light-blocking area of the electrode.

To sum up, an advantage of the present invention is to provide a LED and a method of making the same, wherein the thickness of the substrate is shortened and even eliminated completely, thereby reducing the heat resistance of LED remarkably.

Another advantage of the present invention is to provide a LED and a method of making the same, wherein the carrier under the epitaxial structure can take out the heat generated by the epitaxial structure, thereby reducing the heat resistance of LED remarkably.

Still another advantage of the present invention is to provide a LED and a method of making the same, wherein the reflective layer above the carrier can reflect the light emitted by the epitaxial structure.

Further another advantage of the present invention is to provide a LED and a method of making the same, wherein two electrodes of LED can be disposed on the upper surface of the epitaxial structure and the lower surface of the carrier respectively while the carrier is a conductor, thereby reducing the light-blocking area of the electrode.

As is understood by a person skilled in the art, the foregoing preferred embodiments of the present invention are illustrations of the present invention rather than limitations of the present invention. It is intended to cover various modifications and similar arrangements comprised within the spirit and scope of the appended claims, the scope of which should be accorded the broadest interpretation so as to encompass all such modifications and similar structure.

What is claimed is:

1. A method of making an LED, comprising:
providing a carrier capable of dissipating energy;
providing an epitaxial structure comprising a substrate and a plurality of III-V compound semiconductor epitaxial layers thereby light is generated;
thinning the substrate to a predetermined thickness; and
attaching the carrier to the substrate.

2. The method of making the LED according to claim 1, wherein the substrate is thinned by polishing or etching a portion of the substrate.

3. The method of making the LED according to claim 1, wherein the predetermined thickness is no more than 50 μm.

4. The method of making the LED according to claim 1, wherein the material of the carrier is selected from a group consisting of silicon, GaN, AlN, diamond, and SiC.

5. The method of making the LED according to claim 1, wherein the material of the carrier is selected from a group consisting of copper, silver, aluminum, and gold.

6. The method of making the LED according to claim 1, wherein the carrier is attached to the thinned substrate of the epitaxial structure by an adhesive layer.

7. The method of making the LED according to claim 1, further comprising the step of providing a reflective layer between the substrate and the carrier.

8. The method of making the LED according to claim 7, wherein the material of the reflective layer is selected from a group consisting of silver, gold, and aluminum.

9. The method of making the LED according to claim 6, wherein the adhesive layer is a glue layer.

10. The method of making the LED according to claim 9, wherein the adhesive layer is a transparent heat-conductive glue layer.

11. The method of making the LED according to claim 1, wherein the substrate is a growth substrate where the plurality of III-V compound semiconductor epitaxial layers is grown upon.
